(19) United States
(12) Patent Application Publication
(10) Pub. No.: US 2009/0016019 A1
(43) Pub. Date: Jan. 15, 2009

(54) AIRFLOW CONTROL AND DUST REMOVAL FOR ELECTRONIC SYSTEMS

(75) Inventors: Justin Potok Bandholz, Cary, NC (US); Zachary Benson Durham, Asheboro, NC (US); Clifton Ehrich Kerr, Durham, NC (US); Joseph Eric Maxwell, Cary, NC (US); Kevin Michael Reinberg, Chapel Hill, NC (US); Kevin S. Vernon, Durham, NC (US); Philip Louis Weinstein, Apex, NC (US); Christopher Collier West, Raleigh, NC (US)

Correspondence Address: IBM CORPORATION (SS/NC);c/o STREETS & STEELE, 13831 NORTHWEST FREEWAY, SUITE 355, HOUSTON, TX, 77040, US

(73) Assignee: INTERNATIONAL BUSINESS MACHINES CORPORATION, Armonk, NY (US)

(21) Appl. No.: 11/777,631

(22) Filed: Jul. 13, 2007

(51) Int. Cl. H05K 7/20

(52) U.S. Cl. 361/695; 165/80.3; 361/687

(57) ABSTRACT

Airflow control and dust removal systems and methods are disclosed. In one embodiment, a plurality of blade servers is mounted in a chassis. A blower generates airflow through the chassis. Air enters the chassis uniformly across the blade servers and flows in parallel through the servers. An airflow directing mechanism is provided for allowing airflow through a selected one of the blade servers while reducing or closing airflow to the other blade servers, to individually clean and remove dust from the selected blade server. The airflow directing mechanism may include a movable vane actuated by a rotary or linear solenoid to selectively block airflow ports of the servers. The vane may be held in a closed position, assisted by an electromagnet. The airflow directing mechanism may alternatively comprise a rolled shade having a pattern of openings. The position of the rolled shade may be controlled to align openings in the shade with airflow ports in the servers, to control which servers airflow may pass through.

### BACKGROUND OF THE INVENTION

1. Field of the Invention

The present invention relates to controlling airflow through a computer system and to removing dust from hardware devices included within the computer system.

1. Description of the Related Art

Blowers or fans are used to generate airflow through a computer to cool its components. For example, in an individual personal computer (PC), one or more on-board cooling fans are enclosed within the PC housing that contains the motherboard, power supply, memory, and other internal components. The on-board cooling fan drives airflow through the housing to cool the internal components and exhausts the heated air through the back of the PC. In larger computer systems, such as rack-based computer systems having multiple server blades, one or more external blower modules are supported on a chassis along with the servers to generate airflow through the servers and other components.

The airflow used to cool a computer also carries dust from the computer's environment. Over time, this dust is deposited onto internal components of the computers. To make matters worse, some of the electronic components in computers and servers tend to generate an electrostatic charge that attracts dust as well, increasing the amount and rate of dust being deposited. An accumulation of dust in a computer system can cause a variety of problems, including a reduction in the performance of system components. For example, dust deposited on heatsink fins can reduce the thermal efficiency of the heatsink. Dust can also reduce component life by interfering with operation of moving parts, such as fan blades and mechanical connectors. Dust can reduce the reliability of electrical components by depositing dust particles between electrical contacts in electrical connectors. Dust can even give off a foul odor in the presence of hot components.

The air handling system for the data center is an important part of reducing the amount of dust in the air used to cool the components. However, air filtration and other common precautions are not completely effective against all sources of dust. The entry of a system administrator and the activities performed within the data center can introduce dust into the air as it is being drawn into the components. Over time, there is a likelihood that dust will accumulate on the internal components of the computers.

Once dust is inside the computers, removing that dust conventionally involves manual intervention. For example, most stand-alone single-user PCs have a computer housing that is easily removed or opened for dust removal. Compressed air may be used to direct a gas jet at the surface to be cleaned. However, dust removal is significantly more challenging in larger computer systems, such as multi-server rack systems in data centers, where tens or even hundreds of individual blade servers may be present, along with other system hardware. Cleaning the blade servers may conventionally require first uninstalling and removing all of the blade servers from the rack, and then removing the housing of each blade server to clean them. Thus, removing dust from larger computer systems can be particularly time consuming and costly.

An improved dust removal system and method is needed, particularly in view of the shortcomings of conventional dust removal techniques. Improvements in the speed and ease of dust removal would be especially desirable in larger computer systems such as rack systems having numerous servers and other components.

### SUMMARY OF THE INVENTION

The present invention involves controlling airflow in an electronic system to selectively remove dust from hardware devices, such as servers, without removing the hardware devices from the electronic system.

A first embodiment provides a computer system that includes a plurality of hardware devices and a blower module supported in a chassis. The plurality of hardware devices define a respective plurality of generally parallel airflow passages through the hardware devices. The blower module generates airflow through the plurality of generally parallel airflow passages defined by the hardware devices. An airflow directing mechanism selectively directs airflow through one or more selected hardware devices in response to a signal from a controller.

A second embodiment provides an airflow control system for a computer system. A blower module generates parallel airflow through a plurality of processor blades. An airflow directing mechanism selectively permits airflow through at least one selected processor blade while reducing airflow to the other processor blades. A controller in communication with the airflow directing mechanism generates a signal representative of a selection of servers for which to reduce airflow.

A third embodiment provides a method of controlling airflow through a computer system. Parallel airflow is generated through a plurality of processor blades in a cooling mode. A processor blade is selected to be cleaned in a cleaning mode. Airflow is selectively reduced to a subset of the plurality of processor blades to increase airflow through the selected processor blade.

Other embodiments, aspects, and advantages of the invention will be apparent from the following description and the appended claims.

### BRIEF DESCRIPTION OF THE DRAWINGS

FIG. 1 is a perspective view of a multi-server computer system in which a novel air control and dust removal system according to the invention may be implemented.

FIG. 1A is a schematic side view of a server blade compatible with a multi-server computer system.

FIG. 2 is a schematic plan view of the computer system showing an airflow control system for controlling airflow to the server blades.

FIG. 3 is a schematic plan view of the computer system of FIG. 1 while in a “cleaning mode” of operation, wherein airflow is directed entirely through a selected server blade temporarily for removing dust from the server blade.

FIG. 4 is a schematic plan view of the computer system in an alternative cleaning mode, wherein airflow through the chassis is reversed for enhanced cleaning.

FIG. 5 is a schematic side view of the computer system further illustrating airflow in a particular configuration of the computer system having multiple air outlets per server blade.

FIG. 6 is a schematic side view of the computer system during a cleaning mode, wherein airflow is directed through the center air outlet of the server blade to be cleaned.

FIG. 7 is a schematic side view of the computer system during the cleaning mode, wherein airflow is directed through a selected server blade to the upper plenum.

FIG. 8A is a partially cut-away side view of the computer system illustrating an embodiment of the airflow control system wherein the airflow control devices include movable vanes secured within the chassis.

FIG. 8B is a detailed view of an embodiment wherein the vane is actuated by a rotary solenoid.

FIG. 8C is a detailed view of an alternative embodiment wherein the vane is retained in the closed position by an electromagnet.

FIG. 9A is a perspective view of an alternative airflow directing mechanism comprising a rolled shade placed across a central airflow opening in the midplane between an upper and lower row of electronic connectors.

FIG. 9B is an exploded view of the rolled shade removed from the rollers and laid out flat.

### DETAILED DESCRIPTION

The present invention provides systems and methods for controlling airflow in electronic systems to selectively remove dust from hardware devices such as servers. An electronic system is normally operated with air flow being directed through a plurality of hardware devices in parallel, i.e., air flows through the devices substantially simultaneously rather than consecutively. This parallel air flow removes heat generated by the hardware devices to cool the hardware devices. The present invention provides both a “cooling mode,” wherein the airflow is directed through a plurality of hardware devices in parallel, and a “cleaning mode,” in which airflow is closed or at least reduced to one or more of the hardware devices in order to increase the airflow rate through one or more other hardware devices. This increased airflow provided during the cleaning mode removes dust from the hardware devices through which it flows.

The airflow rate through a hardware device selected to be cleaned during the cleaning mode may be maximized by closing airflow to all of the other hardware devices arranged for parallel airflow with the hardware device being cleaned. Maximizing the airflow rate typically maximizes the cleaning effect. Each device may be cleaned in this manner, such as one at a time, by selectively directing airflow through the device while closing airflow to the other devices. The systems and methods of the invention greatly increase the ease and efficiency of removing dust from hardware devices by allowing the dust to be removed while the hardware devices remain installed in the chassis. Furthermore, the systems and methods can be automated.

The invention is particularly useful with a rack-based system (“rack system”), wherein a plurality of processor blades (e.g. blade servers) is arranged in parallel in a server chassis. In one embodiment, a plurality of blade servers defines a respective plurality of parallel airflow passage through the servers. A blower module disposed in the chassis generates airflow through the chassis. All of the airflow enters the chassis uniformly across the blade servers, which causes parallel and substantially equal airflow through the blade servers during normal operation. An airflow directing mechanism is provided with the rack system for selectively closing or at least reducing airflow to selected blade servers. The management module used to manage the hardware devices may also be configured for operating the airflow directing mechanism. Alternatively, the baseboard management controller provided with each blade server may be used to selectively operate an individual airflow control device provided for controlling airflow through that blade server.

One embodiment of the airflow directing mechanism provides a plurality of vanes rotatably supported in the chassis. Each vane is movable from an open position to a closed position substantially closing or at least reducing airflow through a respective blade server. The vane may be moved by a linear or rotary actuator, such as a linear or rotary solenoid in electronic communication with the management module or the respective baseboard management controller. Optionally, each vane may be formed of a ferrous material, and an electromagnet may be provided to selectively retain the vane in the closed position, to resist air pressure on the back of the vane. Each vane may be biased toward an open position when not actuated, such as using a coil spring, or simply moved between the open and closed position using a motor.

Another embodiment of the airflow directing mechanism comprises a shade having a pattern of openings for selectively permitting airflow to pass through selected blade servers while closing airflow to the other blade servers. The rolled shade may include a sheet of pliable material supported on rollers. The shade is positioned along the primary air transfer opening in the midplane, routed between the midplane and the servers. A notch may be provided in each server to provide clearance for the shade to move between the midplane and the servers. The rolled shade includes a cooling section that permits air to flow through all of the blade servers and a cleaning section for cleaning as few as one blade server at a time. The cooling section may include a long, continuous opening spanning all of the blade servers or a plurality of openings each alignable with one of the blade servers, to permit airflow from each server to flow through the shade and through an opening in the midplane. The cleaning section may include, in a preferred example, a single opening sized to permit airflow through only one selected blade server at a time when the single opening is aligned with the selected blade server, and a continuous section to either side of the opening to close or at least reduce airflow to the other blade servers. The shade may be moved in a direction aligned with a row of air outlets of the blade servers, to align the opening of the cleaning section with the airflow port of the blade server to be cleaned. Thus, the position of the shade determines which server blade(s) airflow will pass through in the cooling mode and in the cleaning mode.

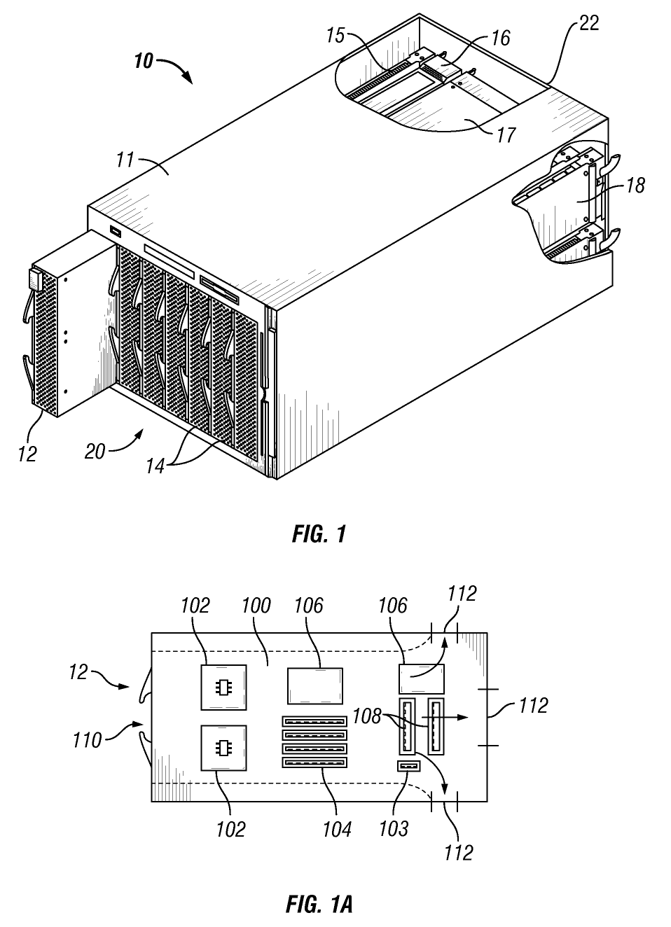

FIG. 1 is a perspective view of a multi-server computer system 10 in which a novel air control and dust removal system according to the invention may be implemented. The computer system 10 includes a chassis 11 that supports a plurality of blade servers 12 and other hardware devices. Each blade server 12 may include one or more microprocessors, hard drives, and memory to service one or more common or independent networks. The computer system 10 includes a variety of shared support modules known in the art, including a chassis management module 15, one or more power supply modules 16, one or more blower modules 17, and multiple switch modules 18. The management module 15 manages the chassis, blade servers, and other modules. The power modules 16 provide power to the system. The blower modules 17 generate airflow through the chassis 11 to cool the computer system. The switch modules 18 provide network connectivity between the blade server I/O and the network. An optional acoustic module (not shown) may be included to reduce noise. The blade servers 12 are installed in the front 20 of the chassis 11 and the support modules 15-18 are installed in the rear 22 of the chassis 11. The blade servers 12 and support modules 15-18 meet at an internal chassis interface known as the midplane, which provides all of the interconnections among the blade servers 12, modules, media tray, and DC power distribution throughout the chassis. Connectors at the midplane couple the blade servers 12 with the support modules 15-18 to reduce wiring requirements and facilitate installation and removal of the blade servers 12.

The blade servers 12 and other system hardware generate heat that must be removed from the system 10 by the blower module 17. For example, microprocessors (“processors”) within the blade servers 12 can get very hot, and a heat sink is installed in contact with each processor to dissipate heat. During a cooling mode of operation, the blower modules 17 generate airflow through the chassis 11 to cool the computer system 10. The net airflow through the chassis 11 during the cooling mode is from the front 20 to the rear 22 of the chassis 11. However, the airflow may be strategically routed in different directions and along multiple airflow paths within the chassis 11, to direct airflow to specific locations. Air enters the computer system 10 through vents 14 in the front of each blade server 12 and passes through the blade servers 12 to cool their internal components. Airflow continues through the chassis 11, to the support modules and other components to be cooled, and eventually passes through the blowers 17 at the rear 22 where the air exits the chassis 11.

In a cooling mode, the airflow typically enters the chassis 11 uniformly across the blade servers 12, a side view of which is schematically shown in FIG. 1A. Each blade server 12 includes a cavity 100 that houses internal server components such as processors and heatsinks 102, DIMMs 104, small form factor (SFF) hard drive 106, and adapter cards 108. Each blade server 12 also includes a baseboard management controller (BMC) 103, which is a specialized microcontroller embedded in the motherboard whose functionality may include receiving input from different sensors and sending an alert to the administrator if any parameters do not stay within predefined limits. Each blade server 12 also includes at least one air inlet 110 and at least one air outlet 112, thus defining an internal airflow passage through the cavity 100 between the air inlet 110 and the air outlet 112. The airflow passage allows airflow to pass through the blade server 12 to cool the internal server components.

Referring again to FIG. 1, the blade servers 12 are arranged side-by-side, such that the airflow passages defined by the blade servers 12 are generally parallel to one another. Thus, all or substantially all of the net airflow through the chassis 11 may flow, in parallel, through the blade servers 12. During the cooling mode of operation, the net airflow generated by the blower module 17 is “divided” among this plurality of generally parallel airflow passages defined by the blade servers. For example, if the net airflow rate through the chassis 11 at an instant were about 70 cu-ft/min, then each of the seven blade servers 12 would experience an individual airflow rate of about 5 cu-ft/min, on average. During the cooling mode of operation, the blower module 17 should generate a net airflow rate large enough to provide each blade server 12 with an individual airflow rate sufficient to cool each blade server 12.

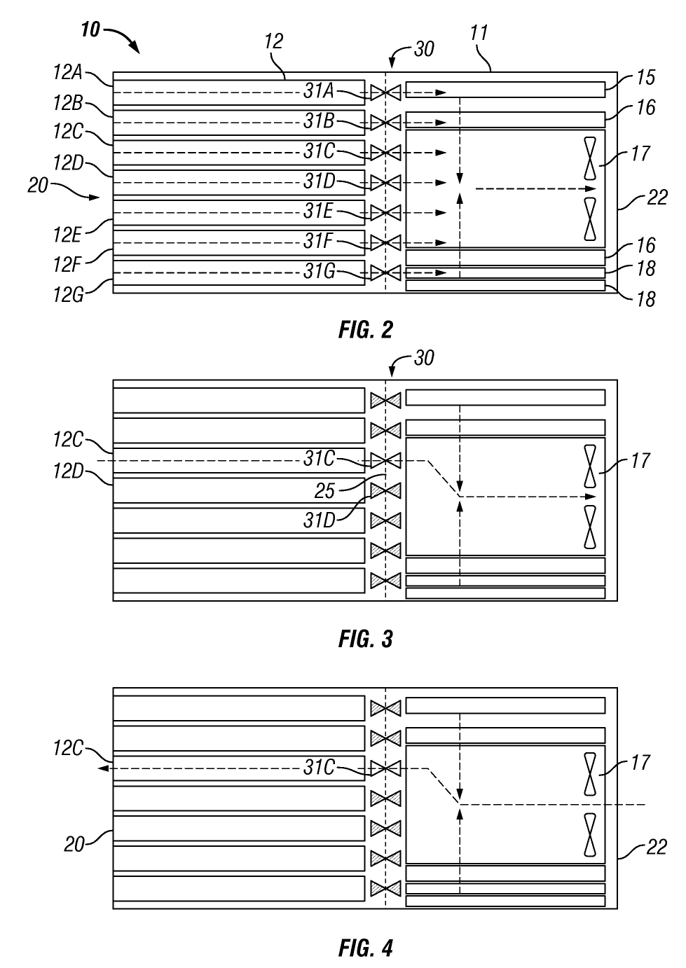

FIG. 2 is a plan view of the computer system 10 with an airflow control system 30 for controlling airflow to the blade servers 12. The airflow control system 30 in this embodiment is schematically illustrated as seven airflow control devices or “valves” 31A-G, collectively referred to as the “airflow directing mechanism 31.” Each valve 31A-G controls the airflow through a respective one of the seven blade servers 12A-G selectively permitting airflow or reducing or closing airflow to the respective blade server. The management module 15 is in electronic communication with each of the valves 31A-G and functions as a controller for operating the valves 31A-G. The computer system 10 is shown in a “cooling mode,” wherein each valve 31A-G is in an open condition (symbolized by an outlined valve) to allow air to flow through all of the blade servers 12 as the blower module 17 moves air through the chassis 11 from the front 20 to the rear 22. The net airflow through the chassis 11 is divided among the plurality of generally parallel airflow passages defined by the blade servers 12. The net airflow may be fairly evenly distributed among the blade servers 12, such that each blade server 12 receives about the same individual airflow rate.

FIG. 3 is a schematic plan view of the computer system 10 of FIG. 1 while in a “cleaning mode” of operation, wherein substantially all of the airflow through the chassis 11 is temporarily directed through a single blade server 12C selected for removing dust from the blade server 12C. The valve 31C remains in the open condition, allowing airflow to pass through the blade server 12C. The other valves 31A-B and 31D-G have been temporarily changed to a closed condition (symbolized by a shaded valve), to close off airflow to the other blade servers 12A-C and 12D-G. Thus, substantially all of the net airflow through the chassis 11 is constrained to travel through the selected blade server 12C, which significantly increases the individual airflow velocity and rate through the selected blade server 12C. Each of the other blade servers 12 may be similarly cleaned, in turn. For example, after the blade server 12C has been cleaned, the valve 31C may be closed, and the adjacent valve 31D may be opened, so that substantially all of the net airflow through the chassis 11 passes through the blade server 12D to clean the blade server 12D. The blade servers 12 may be cleaned in this manner, in any order, such as sequentially from 12A-G.

While in the cleaning mode of FIG. 3, little or no air may be traveling through the blade servers 12A-B and 12D-G. Thus, to prevent overheating of these other blade servers, the cleaning mode may be activated when the blade servers have been observed as being cool, such as during periods of decreased server activity. The cleaning mode may also be performed, for example, with all of the blade servers 12 powered off. This may be conveniently performed during other periods when the servers are powered down for other reasons. In some computer systems, it may be possible to perform the cleaning mode even while the blade servers 12 remain powered on. Sufficient airflow may be generated to clean each blade server quickly, before any of the individual blade servers heat up significantly.

In some systems, the net airflow rate provided by the blower module 17 may be sufficient to clean more than one blade server simultaneously. For example, it may be possible to simultaneously clean blade servers 12C and 12D by opening valves 31C and 31D and closing the valves 31A-B and 31E-F, to direct substantially all of the net airflow through the two blade servers 12C-D. Cleaning the two blade servers 12C-D simultaneously may reduce the overall time required for cleaning all of the blade servers 12 of the computer system 10. However, the airflow rate through each blade server 12C-D will be less than when directing all of the airflow through a single blade server 12C or 12D, which could make cleaning blade servers 12C-D as a pair less effective than when cleaning each blade server 12C-D individually. Thus, the choice to clean each blade server individually or to clean more than one blade server simultaneously will vary with different computer systems in which the invention is implemented. Also, the blower speed may be maximized during the cleaning mode, which can be helpful when cleaning more than one server at a time.

FIG. 4 is a schematic plan view of the computer system 10 in the cleaning mode, but with airflow through the chassis 11 reversed. As in FIG. 3, the valve 31C is in the open condition while the other valves are in the closed condition, to direct substantially all of the airflow through the blade server 12C. However, the direction of airflow has been reversed at the blower module 17, forcing the air to travel through the chassis 11 from the rear 22 to the front 20. This reversal in airflow through the chassis 11 reverses the direction in which airflow passes through the blade server 12C, which may be more effective in removing dust from the blade server 12C. Furthermore, because the front of the blade server 12C is positioned at the entrance to the chassis 11, the dust removed from the blade server 12C is directly expelled from the chassis 11, rather than being moved downstream further into the chassis 11 where it could contaminate other components. It should also be recognized that a quick reversal of the airflow direction may loosen or dislodge dust particles that can then be removed from the blade server with airflow in the normal front to rear airflow direction. This may be desirable, since dust expelled out the front of the chassis has the potential to be immediately reintroduced into one or more adjacent servers due to the overall airflow patterns in the data center. By contrast, by design of the data center, dust expelled out the exhaust is typically drawn out of the data center to be filtered in the computer-room air-condition system (CRAC).

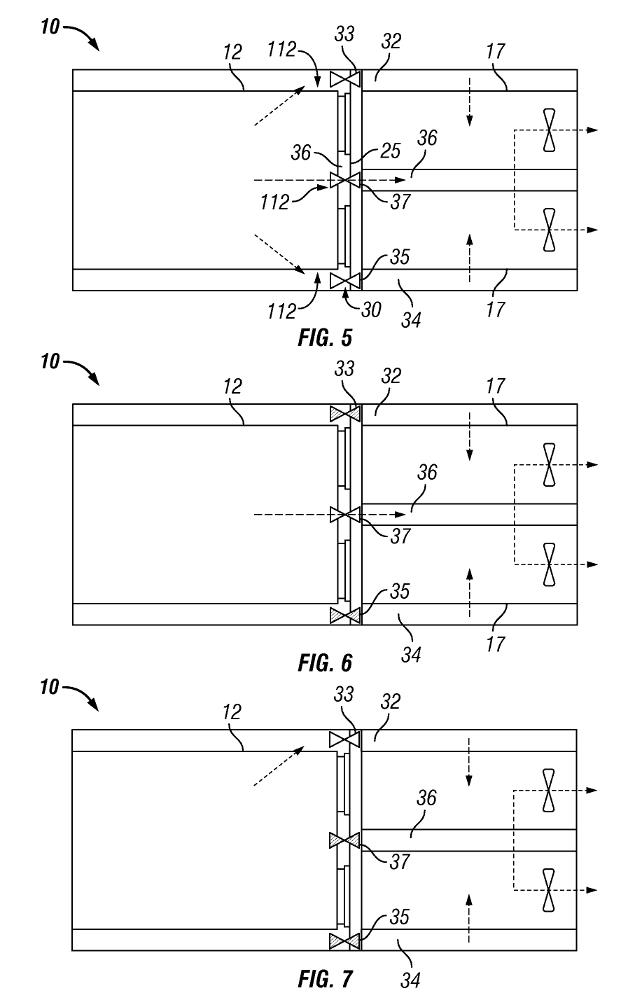

As illustrated in FIG. 1A, some existing blade server systems already include multiple air outlets per blade server, and an airflow control system may be configured according to the invention to provide individual control to each of these air outlets as described with reference to FIGS. 5-7. FIG. 5, for example, is a schematic side view of the computer system 10 wherein airflow is permitted to flow through each of the multiple air outlets 112 (three shown) in an individual blade server 12. Two blower modules 17 are provided for redundancy and to increase airflow. In this configuration, air may exit each blade server 12 at the rear via three separate paths, as indicated using arrows. By horizontal symmetry, the air exits openings 112 in the rear top and bottom of the blade server 12 into an upper plenum 32 and lower plenum 34, respectively, as well as exiting straight through the midplane 25 into a central plenum 36. Airflow through the upper and lower plenums 32, 34 cross over or under the midplane 25, respectively, then turns 90 degrees to proceed through the switch, management, and power-supply modules (FIGS. 1-4), before rejoining the airflow from the rear center of the blade server 12 in the central plenum 36. The air is then pulled into the two blowers 17 and exhausted from the chassis 11. The airflow control system 30 optionally includes airflow control devices 33, 35, 37 schematically shown as valves for controlling flow to the plenums 32, 34, 36. FIG. 5 is shown in the cooling mode, wherein all of the valves 33, 35, 37 of each blade server 12 are open to allow airflow to pass to all three plenums 32, 34, 36.

FIG. 6 is a schematic side view of the computer system 10 during a cleaning mode, wherein airflow is directed through the center air outlet of the blade server 12 to be cleaned. The valves 33, 35 to the upper and lower plenums 32, 34 are closed, while the valve 37 to the central plenum 36 remains open. Simultaneously, all of the valves (upper, lower, and central) of the other blade servers 12 (not shown) in the chassis 11 may be closed, so that substantially all of the airflow is constrained to pass through the selected blade server 12 (shown). Closing the valves 33, 35 leading to the upper and lower plenums 32, 34 increases the airflow velocity directed to the central plenum 36, which may more effectively remove dust from the selected blade server 12, at least in the vicinity of the center of the blade server 12.

FIG. 7 is a schematic side view of the computer system 10 during the cleaning mode, wherein airflow is directed through a selected blade server 12 to the upper plenum 32. The valves 35, 37 leading to the lower and central plenums 34, 36 are closed, while the valve 33 leading to the upper plenum 32 remains open. Again, all of the valves (upper, lower, and central) of the other blade servers 12 (not shown) may be closed, so that all of the airflow through the chassis 11 is directed through the selected blade server 12 (shown). Closing the valves 35, 37 leading to the lower and central plenums 34, 36 increases the airflow velocity directed to the upper plenum 32, which may more effectively remove dust from the selected blade server 12, at least in the vicinity of the upper portion of the blade server 12.

Similarly, if desired, airflow may be alternatively directed to the lower plenum 34 by closing the valves 33, 37 leading to the upper and central plenums 32, 36 and opening the valve 35 leading to the lower plenum 34. By separately directing airflow to each of the upper, lower, and central plenums 32, 34, 36, the selected blade server 12 may be more thoroughly cleaned. Depending on the system, however, the blower modules 17 may provide sufficient airflow in the cleaning mode to clean the selected blade server 12 even with all three of the air outlets to the selected blade server 12 open.

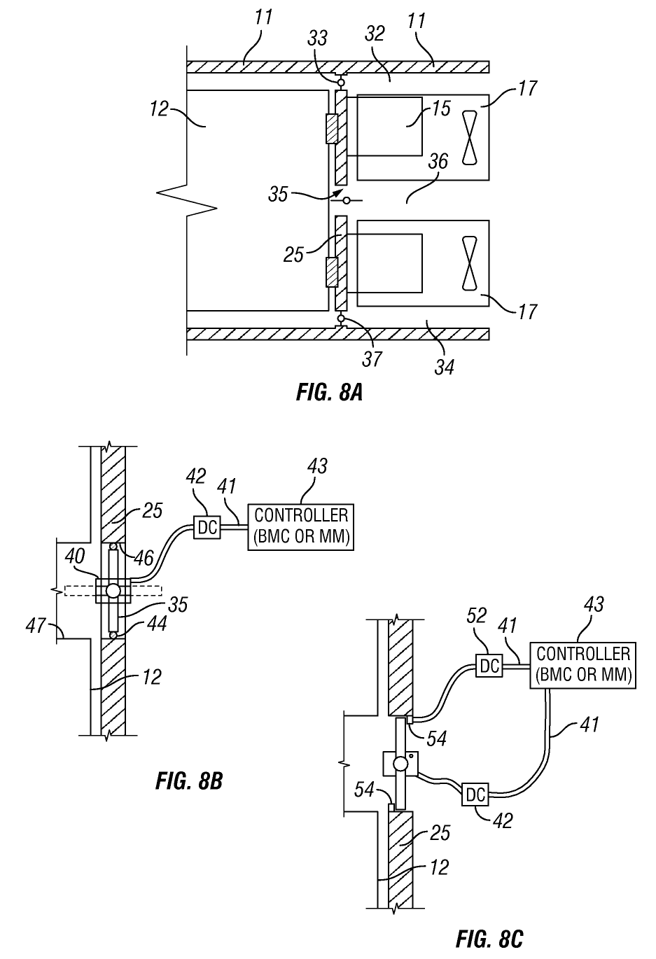

FIG. 8A is a partially cut-away side view of the computer system 10 illustrating an embodiment of the airflow control system wherein the airflow control devices 33, 35, 37 include movable vanes secured within the chassis 11. The BMC 103 (FIG. 1) of each blade server 12 may be used to control the associated vanes. Alternatively, as in this embodiment, the management module 15 may be used to globally control the vanes. The management module 15 is connected to the midplane 25 for electronic communication with actuators for each of the vanes 33, 35, 37. The computer system 10 in FIG. 8A is shown in the cleaning mode, wherein the vanes 33 and 37 have been rotated to a closed position for stopping airflow to the air plenums 32, 34, and the vane 37 is open to allow airflow through the blade server 12 to the central plenum 36. Accordingly, the details shown in FIG. 8A are consistent with the schematic view in FIG. 6. The vanes (upper, lower, and central) associated with the remaining servers (not shown) of the computer system 10 are closed, to direct airflow through the selected blade server 12.

The moveable vanes may be actuated in a variety of ways. FIG. 8B is a detailed side view of an embodiment wherein the vane 35 is actuated by a rotary solenoid 40. One or more signal communication pathways 41 leads to the controller 43 (e.g., BMC or management module), outputting a signal to the rotary solenoid 40 to selectively open or close the vane 35. The communication pathway 41 may be a wire or trace routed through the midplane 25 from the management module 15 (FIG. 8A) to a DC current source 42 that powers the solenoid 40. The DC power source 42 may be configured so that when the DC power source 42 is “ON”, the solenoid 40 moves the vane 35 to a closed position. In the closed position, the vane 35 may seal against a sealing member 44, which may be an O-ring or simply a metal sealing surface on or near the midplane 25, to close airflow to a port 46 aligned with an air outlet 47 of the blade server 12. The vane 35 may be biased to an open position when the DC power source 42 is “OFF.”

FIG. 8C is a detailed side view of an alternative embodiment wherein the vane 35 is retained in the closed position by an electromagnet 54. The vane 35 may again be biased to an open position and selectively urged by the electromagnet 54 to the closed position in response to a signal from the controller 43 (e.g. BMC or management module). The vane 35 may be formed of a ferrous material, so that in the closed position, the vane 35 is retained by the electromagnet 54. For example, when it is desired to close the vane 35, the management module 15 may output a signal to power on the DC source 52 to energize the electromagnet 54 and urge the vane 35 toward a closed position. The rotary solenoid 40 is optionally included to assist the electromagnet 54 in bringing the vane 35 to the closed position. The electromagnet 54 may provide a large retaining force for resisting the air pressure on the back side 55 of the vane 35. Thus, with the use of the electromagnet 54, the size and power of the rotary solenoid 40 may be reduced.

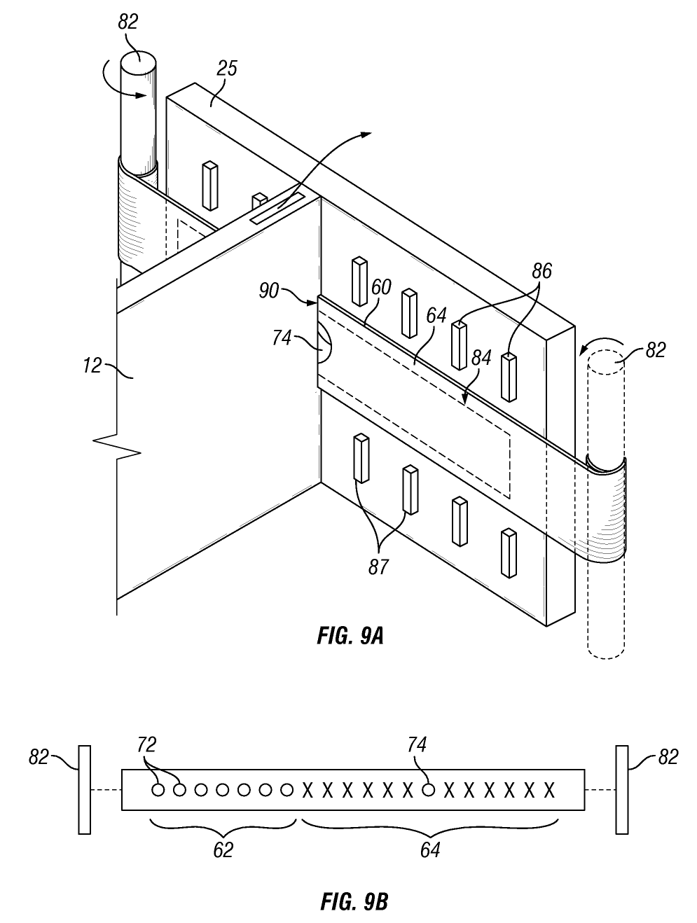

FIG. 9A is a perspective view of an alternative airflow directing mechanism comprising a rolled shade 60 placed across a central airflow opening 84 in the midplane 25 between an upper and lower row of electronic connectors 86, 87. One blade server 12 is connected to one of the upper connectors 86 and one of the lower connector 86 for electronic communication with other components of the rack system. The rolled shade 60 is shown as a sheet of pliable material wound onto a pair of rollers 82. At least one of the rollers 82 may be powered for moving the shade 60 left or right across the midplane 25. A notch 90 is provided in each blade server 12 to accommodate movement of the rolled shade 60. The management module 15 (FIG. 1) may be in communication with the powered rollers, acting as a controller for the rolled shade 60 to control the horizontal movement (left or right) of the shade 60. The shade 60 is shown in the cleaning mode, wherein a cleaning section 64 is positioned across the airflow opening 84 in the midplane 25. An opening 74 in the cleaning section 64 is aligned with the blade server 12, permitting airflow through the blade server 12. The rolled shade simultaneously covers the rest of the central airflow opening 84 in the midplane 25, to block airflow through the other blade servers (not shown). This positioning of the shade 60 causes more airflow to be directed through the blade server 12 shown, for cleaning the blade server 12.

FIG. 9B is an exploded view of the rolled shade 60 removed from the rollers 82 and laid out flat. The rolled shade 60 includes a cooling section 62 and a cleaning section 64. The cooling section 62 has seven openings 72 having a horizontal spacing equal to a spacing of the blade servers 12. The cleaning section 64 includes the single opening 74, surrounded by six “positions” designated by “Xs” on either side of the single opening 74. The portion of the shade 60 that includes the Xs may simply be a continuous, non-perforated portion of the shade 60 sufficient to cover the width of six blade servers on either side. In the cooling mode, the rolled shade 60 may be moved by the rollers 82 to position the cooling section 62 across the blade servers, with each opening 72 aligned with a respective one of the blade servers. Thus, in the cooling mode, the positioning of the rolled shade 60 permits full airflow through each blade server, through the respective opening 72 in the cooling section 62, and through the central opening 84 in the midplane 25, to simultaneously cool all of the blade servers. In the cleaning mode, the rolled shade 60 may be moved by the rollers 82 to position the cleaning section 64 across the blade servers, with the single opening 74 over a selected one of the blade servers. Thus, in the cleaning mode, full airflow is permitted through the selected blade server, through the single opening 74 in the cleaning section 64 of the rolled shade 60, and through the central opening 84 in the midplane 25. Simultaneously, the rolled shade blocks or at least reduces airflow through blade servers on either side of the blade server selected to be cleaned. This may cause most or all of the airflow through the chassis to be directed through the selected blade server, providing an increased airflow rate for cleaning the selected blade server. A similar shade may be provided for controlling airflow through upper and lower openings in the midplane 25, if upper and lower airflow outlets are included with each server blade.

A variety of exemplary embodiments have been described above for controlling airflow and removing dust from hardware devices of a computer system. More generally, the invention also provides a method of controlling airflow through a computer system to remove dust from selected hardware devices. According to one method, parallel airflow is established through a plurality of hardware devices. A hardware device is selected to be cleaned, and airflow is at least reduced (if not closed off completely) to the other devices, so as to redirect the airflow to a selected hardware device and increase the airflow rate through the selected hardware device. Each hardware device may be cleaned in this manner. This method can be implemented using any of the systems disclosed herein. However, other systems for controlling airflow and removing dust using this method are within the scope of the invention.

The systems and methods disclosed herein provide an improved way to remove dust from hardware devices of a computer system, without the complication and inefficiency of having to remove the hardware devices from the chassis and removing the housing of each device every time dust is removed. Rather, by controlling airflow in the manner described, dust may be removed quickly and easily while all of the hardware devices remain installed. Furthermore, this device may be controlled electronically. With the airflow control system installed in a computer system, an automated or semi-automated process may be established for periodic dust removal. For example, the cleaning mode may be performed according to a set schedule, and may be scheduled at convenient times such as during periods of decreased load on the servers. A more thorough cleaning may still be desired occasionally, wherein hardware devices are manually removed, opened, inspected, and cleaned if necessary. However, such manual intervention may be performed far less frequently than in the prior art.

The terms “comprising,” “including,” and “having,” as used in the claims and specification herein, shall be considered as indicating an open group that may include other elements not specified. The terms “a,” “an,” and the singular forms of words shall be taken to include the plural form of the same words, such that the terms mean that one or more of something is provided. The term “one“ or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition or step being referred to is an optional (not required) feature of the invention.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A computer system, comprising:
a chassis;
a plurality of hardware devices supported in the chassis, the plurality of hardware devices defining a respective plurality of generally parallel airflow passages through the hardware devices;
a blower module supported on the chassis for generating airflow through the plurality of generally parallel airflow passages defined by the hardware devices; and
an airflow directing mechanism for selectively directing airflow through selected hardware devices in response to a signal from a controller.

2. The computer system of claim 1, wherein the airflow directing mechanism comprises:
a plurality of vanes pivotally supported in the chassis, each vane being moveable from an open position to a closed position substantially closing an airflow port of a respective one of the generally parallel airflow passages; and
a plurality of actuators in electronic communication with the controller, each actuator for moving an associated one of the vanes to the closed position.

3. The computer system of claim 2, wherein each actuator comprises a rotary solenoid for rotating the associated vane to the closed position.

4. The computer system of claim 2, wherein each vane is biased to the open position.

5. The computer system of claim 2, further comprising a magnet for selectively retaining the respective vane in the closed position.

6. The computer system of claim 1, wherein the airflow directing mechanism comprises a movable shade having a first section and a second section alternatively positionable across the plurality of generally parallel airflow passages, the first section including an opening alignable with a selected one of the airflow passages for permitting airflow through the selected airflow passage while restricting airflow through the other airflow passages, the second section including a plurality of openings each alignable with a respective one of the airflow passages to permit simultaneous airflow through all of the airflow passages.

7. The computer system of claim 6, wherein the shade is connected to one or more rollers selectively rotatable to move the shade portion.

8. The computer system of claim 1, further comprising:
a midplane disposed in the chassis, the midplane including a plurality of openings each generally aligned with a respective one of the generally parallel airflow passages, wherein the airflow directing mechanism limits airflow through the selected hardware devices by substantially closing the openings in the midplane generally aligned with the selected hardware devices.

9. An airflow control system for a computer system, comprising:
a blower module for generating parallel airflow through a plurality of processor blades;
an airflow directing mechanism for selectively permitting airflow through at least one selected processor blade while reducing airflow to the other processor blades; and
a controller in communication with the airflow directing mechanism for generating a signal representative of a selection of servers for which to reduce airflow.

10. The airflow control system of claim 9, wherein the controller comprises one or both of a management module and a baseboard management controller.

11. The airflow control system of claim 9, wherein the airflow directing mechanism comprises:
a plurality of vanes pivotally supported in a chassis of the computer system, each vane being moveable from an open position to a closed position substantially closing an airflow port of a respective one of the generally parallel airflow passages; and
a plurality of actuators in electronic communication with the controller, each actuator for moving an associated one of the vanes to the closed position.

12. The airflow control system of claim 11, wherein each actuator comprises a rotary solenoid for rotating the associated vane to the closed position.

13. The airflow control system of claim 11, further comprising one of a baseboard management controller and a management module in communication with the actuators for controlling movement of the vanes.

14. The airflow control system of claim 11, further comprising a magnet for selectively retaining the respective vane in the closed position.

15. The airflow control system of claim 9, wherein the airflow directing mechanism comprises a movable shade having a first section and a second section alternatively positionable across the plurality of generally parallel airflow passages, the first section including an opening alignable with a selected one of the airflow passages for permitting airflow through the selected airflow passage while restricting airflow through the other airflow passages, the second section including a plurality of openings each alignable with a respective one of the airflow passages to permit simultaneous airflow through all of the airflow passages.

16. The airflow control system of claim 15, wherein the shade is connected to one or more rollers selectively rotatable to move the shade portion.

17. A method of controlling airflow through a computer system, comprising:
generating parallel airflow through a plurality of processor blades in a cooling mode; and
selectively reducing airflow to a subset of the plurality of processor blades to increase airflow through a processor blade selected to be cleaned in a cleaning mode.

18. The method of claim 17, wherein the step of reducing airflow to the other processor blades comprises moving a vane to a position covering an airflow port of each of the other processor blades.

19. The method of claim 17, further comprising:
reversing the direction of airflow through the processor blades.

20. The method of claim 17, further comprising:
reducing power to the subset of processor blades during the period of reduced airflow.
